(19) United States
(12) Patent Application Publication
(10) Pub. No.: US 2008/0296757 A1
(43) Pub. Date: Dec. 4, 2008

(54) Fluid spreader

(76) Inventors: Paul Hoffman, San Diego, CA (US); Rajiv Tandon, San Diego, CA (US); Chun-Hou Chan, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/806,089

(22) Filed: May 30, 2007

(51) Int. Cl. H01L 23/34

(52) U.S. Cl. 257/713; 401/25; 401/5; 427/98.6; 257/E23.08

(57) ABSTRACT

A fluid spreader includes a first surface, wherein the first surface has at least one channel that continuously or discontinuously extends to an outer periphery of the first surface, allowing fluid to flow easily and thereby reducing the thickness of the fluid between the fluid spreader and another device or component.

### BACKGROUND OF THE INVENTION

1. Field of the Present Invention

The present invention generally relates to a fluid spreader, and more particularly, to a fluid spreader that has at least one channel or protrusion to decrease the thickness of the fluid located between one or more areas of the fluid spreader and a second component or multiple secondary components.

2. Description of the Related Art

A Thermal Interface Material (referred to as TIM), which is defined as a material with better thermal conductivity than air, has been commonly used to fill between surfaces of semiconductors and heat sinks or heat spreaders, in order to increase thermal transfer efficiency. The TIM has many forms. The most common one for IC packaging or electronics assembly is a white-colored paste or thermal grease, such as silicone oil with aluminum oxide, zinc oxide, or boron nitride filler particles.

As the operational speed of Integrated Circuits (ICs) gets faster or the number of circuits increase, or the IC power level increases, the heat generated from the IC increases significantly. For better heat dissipation, it is required that the TIM should have high thermal conductivity, minimal thickness, small or preferably no voids in the TIM and at the interface thereof, and good adhesion between IC chip and heat sink and/or heat spreader. The same is true of TIM materials used in the cooling or heating of other systems—whether they are based on ICs, electronic modules, or other electronic or non-electronic heat or cold-generating devices.

Typically, the heat sinks consist of a plate with one or more flat surfaces and an array of protruded fins to enlarge the surface area contacting with the air or other heat transfer fluid, and therefore increasing the heat dissipation rate. If the heat transfer fluid is a liquid then the heat transfer structure is often referred to as a cold plate. If the heat transfer structure's purpose is mainly to provide good heat transfer from a small area heat or cold source (e.g. an IC chip as a heat source) by conduction to a larger area then the heat transfer structure is often referred to as a heat spreader. The concepts discussed herein can be equally applied to heat spreaders, cold plates and heat sinks, vapor chambers and the like. The heat transfer structures are usually made of aluminum or copper due to their good thermal conductivity of 237 and 401 W/mK, respectively. However, a great decrease of the thermal transfer efficiency between the heat transfer structures and the IC chips or other heat or cold sources occurs due to unsmooth contact areas there between. The TIMs are used to mediate between the heat transfer structures and the heat or cold sources or components to cure such an insufficiency.

Roughness of a contact surface will more or less affect the contact area at the interface of the TIM and the heat transfer surfaces, no matter how flat the surface is. In a conventional flat heat transfer structure, if voids exist at the interface of TIM and the heat transfer structure, the heat transfer efficiency will reduce due to the decreased contact surface between the heat transfer structure and TIM. Furthermore, the thickness of TIM also significantly affects the heat transfer efficiency between TIM and the heat transfer surfaces. The thinner the TIM the better the heat transfer efficiency. The TIM is typically the most significant thermal resistance that affects the heat transfer from the heat or cold source to the heat transfer structure—often accounting for 50% to 70% of that thermal resistance. This is due to the fact that the thermal conductivity of the TIM materials is so low (typically in the range of 1 to 4 W/mK) or 2 orders of magnitude lower than aluminum or copper.

Therefore, there is a need of a fluid spreader such as a heat transfer structure in semiconductor IC and other fields, which has improved heat transfer efficiency for TIM.

### SUMMARY OF THE INVENTION

It is one object of the invention to provide a fluid spreader that increases the contact area to the fluid (TIM or other fluid).

It is another object of the invention to provide a fluid spreader that helps fluid to flow through channels formed on its surface in a predetermined direction.

It is still another object of the invention to provide a fluid spreader that reduces the thickness of TIM or fluid between the spreader and a secondary component or components (e.g. a heat source (such as a chip in a semiconductor package) or cold source) so as to increase the heat transfer from the heat or cold source to the spreader or to derive some other benefit by way of the reduced fluid thickness.

It is yet another object of the invention to provide a fluid spreader that improves the flow of fluid or TIM between the spreader and a secondary component or components such that the force applied to the fluid spreader to promote that fluid flow is substantially reduced in comparison to a fluid spreader or heat transfer structure without channels or protrusions.

In order to achieve the above and other objectives, the fluid spreader of the invention includes a first surface, wherein the first surface has at least one channel that extends to the outer periphery of the first surface.

In one embodiment of the invention, at least two channels are formed parallel or non-parallel to one another, configured in symmetrical or asymmetrical manner and arranged in equal or different intervals. Channels in this embodiment may also be arranged in radial patterns extending outward from the interior of the fluid spreader.

In another embodiment of the invention, the channel has a convex, semi-circle, V-shaped or other non-rectangular profile.

In still another embodiment of the invention, the channel includes surface textures or protrusions, such as serrated edges, on internal sidewalls or the floor of the channel. These features can be used to affect the flow of the fluid through the channels (e.g. making flow easy in one direction and difficult in another direction).

In another embodiment of the invention the fluid spreader comprises a first surface and a second surface or multiple secondary surfaces, with the first surface and at least one of the secondary surfaces also having channel features as described elsewhere in this invention. In some embodiments the fluid spreader will have a first surface with at lease one channel and a second surface opposite to the first surface that also has at least one channel. In other embodiments the fluid spreader will have a first surface with at least one channel and several secondary surfaces orthogonal to the first surface also with at least one channel (e.g. a cube with channels on multiple faces). In yet other embodiments the first and secondary surfaces are not flat and their relationship to each other may be of varying geometry.

In another embodiment of the invention the channels on the first and secondary surfaces may be of radically different scale (e.g. 150 um to 300 um channel width on one surface and 300 um to 1000 um channel width on another surface) to better match to the properties of the fluid or TIM in contact with each surface.

In yet another embodiment of the invention, there may be on one surface several areas or patches of channels with different scale, orientation or other unique features described elsewhere in this invention, to allow fluid flow to be affected in different ways relative to the patch the fluid is flowing through.

In another embodiment of the invention there could be two or more different types of fluids or thermal interface materials used in different areas on the surface with channels, such as a low flow fluid in the central portion of the surface and a high flow, low viscosity fluid on the peripheral portions of the surface.

In another embodiment of the invention the channels may be so wide as to create distinct pedestals or protrusions on the surface of the fluid spreader. These pedestals or protrusions can be preferentially located to correspond to hot spots, cold spots or other specific areas on the mating component (e.g. electronic component or IC chip) to preferentially affect the properties of the fluid or the fluid interaction with the components and fluid spreader in that location. For example, protrusions on the fluid spreader could decrease the TIM thickness local to those protrusions and those protrusions could correspond to hot spots on an IC chip—the thinner TIM material improving the heat transfer between those hot spots and the fluid spreader/heat transfer structure and preferentially cooling those hot spots more effectively in comparison to a heat transfer structure without protrusions.

In another embodiment of the invention the first surface could have areas of several different levels or planes—in order to affect the fluid thickness and flow between two or more corresponding components. For example, the fluid spreader could have sections at three distinct levels to contact three separate ICs on a multi-chip module or System-in-Package.

In a further embodiment of the invention fluid spreaders or components with channels formed in them to affect fluid flow and thickness can be arranged opposed to one another, thereby further reducing the fluid or TIM thickness between those two opposed surfaces.

In another embodiment of the invention the surface has not only channels, but also reservoirs (sections of the surface with higher geometric volume than the channels) that can be used to store excess fluid flow or can be used as a source of fluid to flow into the channels.

In another embodiment of the invention the channels are fully terminated within the periphery of the fluid spreader; specifically the channels do not extend out to the periphery. In this case, since the channels have no direct outlet for the fluid or TIM flow, the amount of fluid or TIM material must be controlled such that the material flows easily within the channels and between the surface of the fluid spreader and the component.

Furthermore, the invention also provides a semiconductor package including at least a fluid spreader, a semiconductor chip and a TIM layer between the fluid spreader and the chip, wherein the fluid spreader has a plurality of channels on a first surface thereof with varying widths along the whole channel. The fluid spreader is a heat transfer structure.

To provide a further understanding of the present invention, the following detailed description illustrates embodiments and examples of the present invention, this detailed description being provided only for illustration of the present invention.

### BRIEF DESCRIPTION OF THE DRAWINGS

FIG. 1 is a top view of a fluid spreader according to one embodiment of the invention.

FIG. 2 is a cross sectional view of a fluid spreader with channels of different widths according to one embodiment of the invention.

FIG. 3 is a cross sectional view of a fluid spreader with channels of varying depths according to one embodiment of the invention.

FIG. 4 is a cross sectional view of a fluid spreader with channels of different profiles according to another embodiment of the invention.

FIG. 5 is a top view of a heat transfer structure with channels having serrated edges along internal sidewalls of channels according to one embodiment of the invention.

FIG. 6 is a cross sectional view of a fluid spreader of FIG. 2 applied to a heat source (such as a semiconductor IC or IC package) or a cold source according to one embodiment of the invention.

FIG. 7 is a cross sectional view of a fluid spreader of FIG. 4 applied to a semiconductor package according to another embodiment of the invention.

FIG. 8 is a cross sectional view of a fluid spreader with channels of such large width that the structure is essentially of a plate with protrusions or pedestals.

FIG. 9 is a cross sectional view of a fluid spreader of FIG. 8 applied to a semiconductor package according to another embodiment of the invention.

FIG. 10 is a tops sectional view of a fluid spreader with channels on opposite surfaces according to another embodiment of the invention.

FIG. 11 is a top view of a fluid spreader with two or more non-parallel surfaces, with two or more of those surfaces having channels according to another embodiment of the invention.

FIG. 12 is a cross sectional view of two fluid spreaders, heat transfer structures or components (in any combination thereof), each with its own channel surface, the fluid spreaders, heat transfer structures or components arranged such that the surfaces with channels are opposing each other in order to minimize the thickness of the fluid dispersed between the surfaces according to another embodiment of the invention.

FIG. 13 is a cross sectional view of a fluid spreader with a first surface of two or more levels, each level with channels, applied to two or more discrete devices (such as semiconductor ICs or IC packages) according to another embodiment of the invention.

FIG. 14 is a cross sectional view of a fluid spreader with certain channel areas that have flow restrictors (such as ridges, pin fin arrays, small walls, porous material or other similar devices that impede fluid flow)according to another embodiment of the invention.

FIG. 15 is a cross sectional view of a fluid spreader with protrusions or stand-offs that provide a specific height or thickness differential between the fluid spreader and the component or device according to another embodiment of the invention.

FIG. 16 is a top view of a fluid spreader with segmented channels (i.e. not continuous channels) according to another embodiment of the invention.

FIG. 17 shows a top view of an outside surface of a fluid spreader according to one embodiment of the invention.

FIG. 18 (A) is a cross-sectional view of a fluid spreader taken along the line A-A_in FIG. 17.

FIG. 18(B) is cross-sectional view, showing a vacuum pick-up head is placed on a central area of the fluid spreader according to one embodiment of the invention.

### DETAILED DESCRIPTION PREFERRED EMBODIMENTS

Wherever possible in the following description, like reference numerals will refer to like elements and parts unless otherwise illustrated.

The invention relates to a flow spreader with channels that can guide a fluid flow through the channels while minimizing fluid voids generated at any interfaces and while minimizing the thickness of the fluid between the opposing surfaces of the fluid spreader and another object. The term “fluid” hereafter refers to any fluid that inherently flows at room temperature or becomes flowable at some operation temperature, melting temperature or some other defined temperature without respect to any limit to the viscosity of the fluid.

Note that the primary objective to reduce the thickness of the TIM (the thickness between the heat or cold source and the heat transfer structure) has analogs in other applications and fields. For example, the structures that will be described in the present invention, could be used in any application where the intent is to reduce the thickness of a fluid interface material (for example between a piston and cylinder, or shaft and bushing, or lens assemblies, or any other application that can be appreciated by someone skilled in the art). In these cases the fluid interface material's primary purpose may not be for heat transfer but for some other purpose (e.g. a lubricant such as grease or oil, a dielectric fluid to affect electromagnetic properties or other). Such a fluid interface could also be useful to minimize bond line thicknesses for many different types of joining applications—whether the joining process is accomplished by use of adhesives or glues, or by soldering or brazing materials, or other joining materials that fall under our broad nomenclature of fluid. These materials may or may not be a liquid or paste material at room temperature and in some cases would only become a flowable liquid at some elevated temperature.

In the case that the fluid is a TIM, a TIM used in contact with a heat transfer structure includes various materials such as thermal greases, phase change materials, thermal adhesives, thermally conductive compounds, solders, liquid metals, braze alloys, thermally conductive elastomers, thermally conductive adhesive tapes, and thermally conductive pads. All those TIMs are flowable at room temperature or at operation temperatures with different viscosities. Other fluids that are relevant to the invention are lubricants such as oils and greases, joining materials such as adhesives, soldering alloys, brazing alloys and the like, and any other fluid that would benefit an application by a reduction in that fluids thickness.

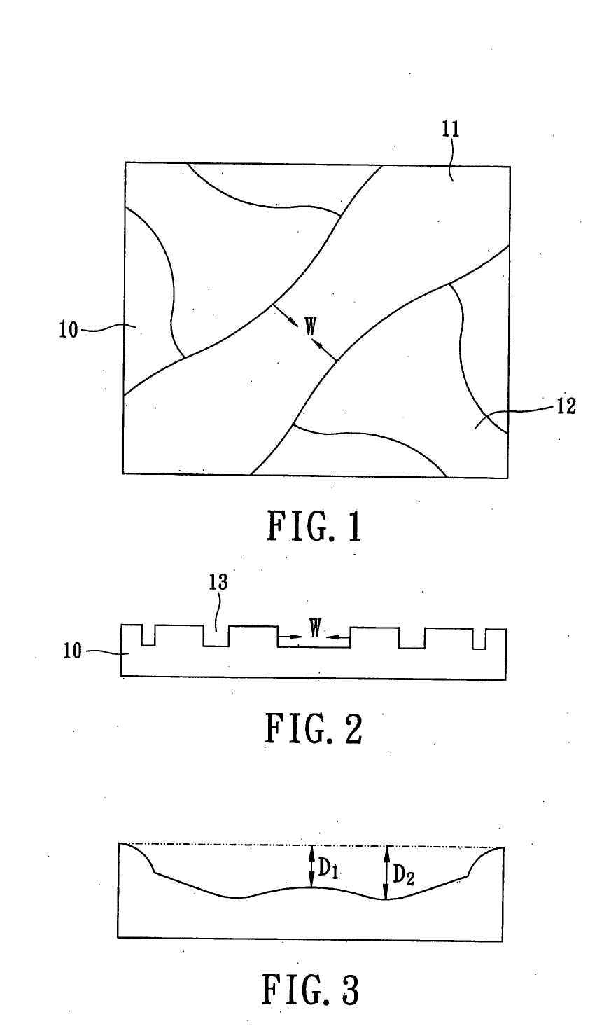

FIG. 1 is a top view of a fluid spreader according to one embodiment of the invention. Referring to FIG. 1, the fluid spreader of the invention includes a first surface, wherein the first surface has at least one channel 11 that extends to the outer periphery of the first surface. The fluid spreader of FIG. 1 has channels 11 of various widths W. In this embodiment, a first channel 11 is formed along the diagonal direction from left bottom to right top of the first surface, with width W gradually narrowing down from both ends toward the center of the first surface. In the embodiment shown in FIG. 1, a second channel 12 can be formed from right bottom to left top of the first surface, substantially non-parallel to the first channel 11. The second channel 12 may vary its width W in a different way in comparison to the first channel 11. Specifically, the width W of the second channel 12 gradually broadens from both ends towards the middle. Other variations of the channel width W in different ways are within the scope of the invention. For example, each of the channels 11, 12 has a plurality of sub-sections with different widths. Even though the two channels 11, 12 are configured in non-parallel fashion in FIG. 1, the two channels 11, 12 can be arranged in parallel as well. In the case that the channels 11, 12 are arranged in parallel, they can be formed in symmetrical or asymmetrical manner at equal or different intervals. Channels in this embodiment may also be arranged in radial patterns extending outward from the interior of the fluid spreader. Alternatively, channels can be fully terminated within the periphery of the fluid spreader; specifically the channels do not extend out to the periphery. All the internal sidewalls of the channels may be smooth to reduce any friction between the flowing fluid and the fluid spreader. For each channel, the sides are preferably configured in symmetrical manner for the fluid to smoothly flow and completely fill up the whole channel, increase the contact area between the fluid and the heat transfer structure and reduce the fluid thickness. Even though two channels 11, 12 formed non-parallel to each other as shown in FIG. 1, the way to vary width W for the channels and the number of channels formed on the first surface are not limited.

Smooth internal sidewalls of the channels help reduce the friction between the flowing fluid and the fluid spreader, and to fill the fluid completely up in the channels. Furthermore, smaller contact area between the fluid and spreader due to the varying width of channel improves the heat transfer to the spreader. In addition, the configuration of channels in the fluid spreader contributes to the reduction of the fluid thickness that shortens the distance between the first surface and a second component or components surface(s) and therefore significantly enhances heat transfer and other properties.

FIG. 2 is a cross sectional view of a fluid spreader with channels of different widths according to one embodiment of the invention. Even though the fluid spreader is illustrated by exemplifying a fluid spreader with channels 13 with different widths but same depth as shown in FIG. 2, the variation of depth in combination with the variation of widths for the channels 13 of the fluid spreader is also in the scope of the invention. In this embodiment, those channels 13 of different widths can be arranged in equal or different intervals, in parallel or non-parallel manner. Channels in this embodiment may also be arranged in radial patterns extending outward from the interior of the fluid spreader. Alternatively, channels can be filly terminated within the periphery of the fluid spreader; specifically the channels do not extend out to the periphery.

FIG. 3 is a cross sectional view of a fluid spreader with channels of varying depths according to one embodiment of the invention. The depth of the channel varies from one section of the channel to another section of the channel, in a lengthwise direction along the channel. Referring to FIG. 3, the depth of at least one of the channels varies from one portion of the channel 13 to another portion of the channel 13. For example, the depth D1 at the middle is smaller than the depth D2 of the neighborhood area. The change in depth in one channel can be regular or irregular, symmetrical or asymmetrical. The changes in depth in one channel can be similar or dissimilar to the changes in depth in any of the other channels. The more the depth varies the more the affect on the fluid flow.

In the case that the fluid spreader is a heat transfer structure, it needs not only to reduce the thickness of the fluid between a first surface of the heat transfer structure and a component or device, but also to completely fill up all the channels on the first surface of the heat transfer structure with the fluid. That is, it is preferable not to form any voids at the interfaces of the channels and the fluid, especially around intersections of sidewalls and bottoms of the channels. Therefore, with a given channel, the bottom profile of the channel is preferable gradually changed.

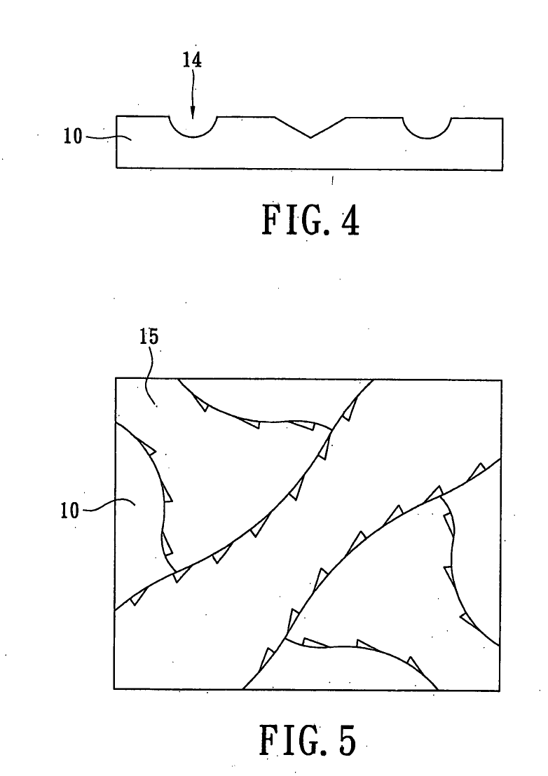

FIG. 4 is a cross sectional view of a fluid spreader with channels of different profiles according to another embodiment of the invention. Referring to FIG. 4, the profile of one of the channels 14 can be convex, semi-circle, V-shaped or any other profile. All the channels 14 can have the same or different profiles. Furthermore the profiles can vary along the length of any channel 14. If all or some of channels 14 have different profiles, the channels 14 of different profiles can be arranged to sandwich between the channels 14 of same profiles, in group or individually. Those channels 14 in this embodiment can also have the similar surface features as described above.

The fluid is flowable at room temperature, operation temperature or some other temperature and the flow speed is determined by its viscosity. In order to help the fluid flow along a preferred direction in the channels 15, some surface textures or surface features can be added to the internal sidewalls of the channels 15 to guide elements of the fluid flow near the internal sidewalls in the on-going direction, as shown in FIG. 5. That is, these surface features are used to make flow easy in one direction or difficult in another direction, as desired. For example, a plurality of serrated edges is formed along at least one internal sidewall of at least one channel 15. The shape, number and tile angle relative to the internal sidewalls of the serratations are not particularly limited, and it is determined based on the application of the flow spreader. For example, the number of serrated edges for low-viscosity fluid is larger than number for high-viscosity fluid. Furthermore, the serrated edges can be regularly or irregularly formed on one side or both sides, in symmetrical or asymmetrical way. In the case that the fluid is inherently flowable at normal temperature, the serrated edges on the sidewalls of the channels are very helpful in guiding the fluid to flow in one way. For both of the above cases, adding the edges on the sidewalls can impede the fluid from flowing in a reverse direction which disadvantageously disturbs the movement of the fluid to leave an empty section in the channels 15. Furthermore, the serrated edges also contribute to the increase of contact area between the fluid and the first surface of the fluid spreader.

In some embodiments, the fluid spreader has a first surface with at lease one channel and a second surface opposite to the first surface that also has at least one channel. Each channel extends to an outer periphery of its corresponding surface, which has at least one of the surface features as defined above. The channels can be formed parallel or non-parallel to one another. If the channels are formed parallels, they are arranged at equal or different intervals. Channels in this embodiment may also be arranged in radial patterns extending outward from the interior of the fluid spreader. Alternatively, channels can be fully terminated within the periphery of the fluid spreader; specifically the channels do not extend out to the periphery. In other embodiments, the fluid spreader has a first surface with at least one channel and several secondary surfaces orthogonal to the first surface also with at least one channel (e.g. a cube with channels on multiple faces). Each channel extends to an outer periphery of its corresponding surface, which has at least one of the surface features as defined above. Channels in this embodiment may also be arranged in radial patterns extending outward from the interior of the fluid spreader. Alternatively, channels can be fully terminated within the periphery of the fluid spreader; specifically the channels do not extend out to the periphery. Furthermore, channels in this embodiment could extend out to the periphery on one or more surfaces of the fluid spreader and would not extend out the periphery on one or more separate surfaces. In yet other embodiments, the fluid spreader has a first and several secondary surfaces, all of which are not flat and their relationship to each other may be of varying geometry. Each channel extends to an outer periphery of its corresponding surface, which has at least one of the surface features as defined above. Channels in this embodiment may also be arranged in radial patterns extending outward from the interior of the fluid spreader. Alternatively, channels can be fully terminated within the periphery of the fluid spreader; specifically the channels do not extend out to the periphery.

In another embodiment of the invention the channels on the first and secondary surfaces may be of radically different scale (e.g. 150 um to 300 um channel width on one surface and 300 um to 1000 um channel width on another surface) to better match to the properties of the fluid in contact with each surface. Channels in this embodiment may also be arranged in radial patterns extending outward from the interior of the fluid spreader. Alternatively, channels can be fully terminated within the periphery of the fluid spreader; specifically the channels do not extend out to the periphery. In yet another embodiment of the invention, there may be on one surface several areas or patches of channels with different scale, orientation or other unique features described elsewhere in this invention, to allow fluid flow to be affected in different ways relative to the patch the fluid is flowing through.

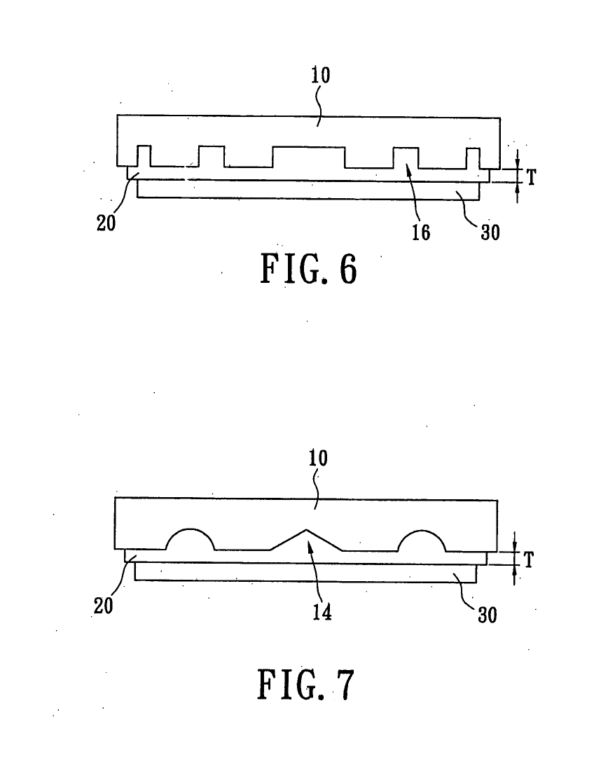

In another embodiment of the invention there could be two or more different types of fluid interface materials used in different areas on the surface with channels, such as a low flow fluid in the central portion of the surface and a high flow, low viscosity fluid on the peripheral portions of the surface. Channels in this embodiment may also be arranged in radial patterns extending outward from the interior of the fluid spreader. Alternatively, channels can be fully terminated within the periphery of the fluid spreader; specifically the channels do not extend out to the periphery. FIG. 6 is a cross sectional view of a fluid spreader of FIG. 2 applied to a semiconductor package according to one embodiment of the invention. The semiconductor package includes at least a fluid spreader 10, a fluid layer 20 and an IC chip 30. The fluid spreader 10 in this embodiment is a heat transfer structure that has been well defined in the art, and therefore the detailed description of its material and functions can be omitted here. The heat transfer structure 10 has a plurality of channels 16 with different widths on its first surface. The channels 16 are arranged with various distances away from one another. The fluid (e.g. TIM in the case of an IC) is typically applied to the IC chip 30 or the fluid spreader 10 and then the fluid spreader 10 is pressed together with the IC chip 30, forcing the fluid to flow through the channels 16 and fill up therein so as to prevent any voids generated at interfaces of the channels 16 and the fluid and to insure the fluid flows and contacts the full surface of the IC chip. Thereby, for a given amount of fluid, the thickness T of the fluid layer 20 between the first surface of the sink 10 and the IC chip 30 is much reduced compared to the conventional one in which the heat transfer structure 10 has no channels 16. Channels 16 in this embodiment may also be arranged in radial patterns extending outward from the interior of the fluid spreader. Alternatively, channels 16 can be fully terminated within the periphery of the fluid spreader; specifically the channels 16 do not extend out to the periphery. In the case that the channels 16 are fully terminated within the periphery of the fluid spreader, since the channels 16 have no direct outlet for the fluid or TIM flow, the amount of fluid or TIM material must be controlled such that the material flows easily within the channels 16 and between the surface of the fluid spreader and the component. FIG. 7 is a cross sectional view of a fluid spreader of FIG. 4 applied to a semiconductor package according to another embodiment of the invention. The semiconductor package includes at least a fluid spreader 10, a fluid layer 20 and an IC chip 30. The fluid spreader 10 in this embodiment is a heat transfer structure that has been well defined in the art, and therefore the detailed description of its material and functions can be omitted here. The heat transfer structure 10 has a plurality of channels 14 with different profiles on its first surface. The channels 14 are arranged with various distances away from one another. All the channels 14 can have the same or different profiles. If all or some of channels 14 have different profiles, the channels 14 of different profiles can be arranged to sandwich between the channels 14 of same profiles, in group or individually. The fluid (e.g. TIM in the case of an IC) is typically applied to the IC chip 30 and then the fluid spreader 10 is pressed together with the IC chip 30, forcing the fluid to flow through the channels 14 and fill up therein so as to prevent any voids generated at interfaces of the channels 14 and the fluid and to insure the fluid flows and contacts the full surface of the IC chip. Thereby, for a given amount of fluid, the thickness T of the fluid layer 20 between the first surface of the sink 10 and the IC chip 30 is much reduced compared to the conventional one in which the heat transfer structure 10 has no channels 14. Channels 14 in this embodiment may also be arranged in radial patterns extending outward from the interior of the fluid spreader. Alternatively, channels 14 can be fully terminated within the periphery of the fluid spreader; specifically the channels 14 do not extend out to the periphery. In the case that the channels 14 are fully terminated within the periphery of the fluid spreader, since the channels 14 have no direct outlet for the fluid or TIM flow, the amount of fluid or TIM material must be controlled such that the material flows easily within the channels 14 and between the surface of the fluid spreader and the component. In another embodiment of the invention the channels may be so wide as to create distinct pedestals or protrusions on the surface of the fluid spreader. These pedestals or protrusions can be preferentially located to correspond to hot spots, cold spots or other specific areas on the component (e.g. IC chip) to preferentially affect the properties of the fluid or the fluid interaction with the components and fluid spreader in that location. For example, protrusions on the fluid spreader could decrease the TIM thickness local to those protrusions and those protrusions could correspond to hot spots on an IC chip—the thinner TIM material improving the heat transfer between those hot spots and the fluid spreader/heat transfer structure and preferentially cooling those hot spots in comparison to a heat transfer structure without protrusions.

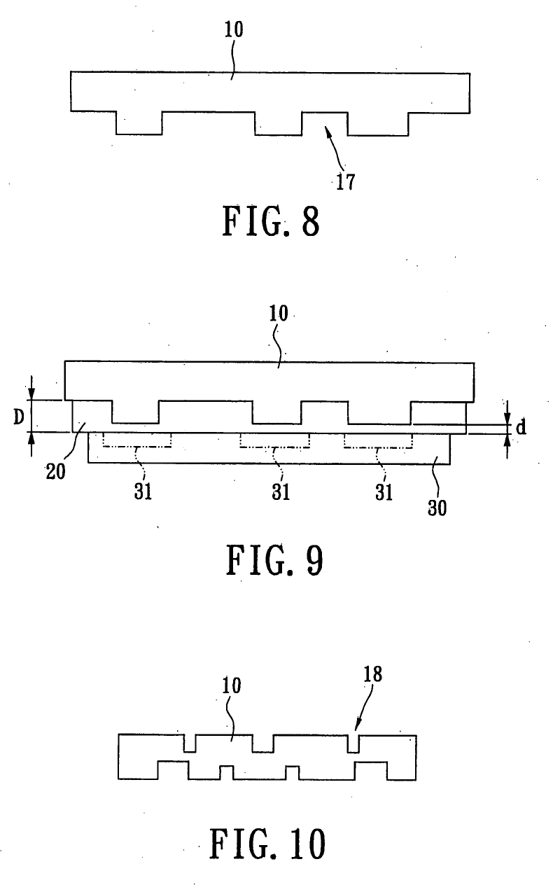

FIG. 8 is a cross sectional view of a fluid spreader 10 with channels 17 of such large width that the structure is essentially of a plate with protrusions or pedestals. These protrusions or pedestals, if used for IC packaging, would typically be in the range of 8 microns to 50 microns tall (distance from the fluid spreader surface to the top of the protrusion or pedestal). The area of each of the pedestals could be from tens of square microns to tens of square millimeters. Although not shown in the figure, each of the pedestals or protrusions could itself have channels 17 as described elsewhere in this invention.

In another embodiment of the invention the first surface could have areas of several different levels or planes—in order to affect the fluid thickness and flow between two or more corresponding components. For example, the fluid spreader could have sections at three distinct levels to contact three separate ICs on a multi-chip module or System-in-Package.

FIG. 9 is a cross sectional view of a fluid spreader 10 of FIG. 8 applied to a semiconductor IC package 30 according to another embodiment of the invention. In this case the pedestals on the fluid spreader are preferentially located to coincide with hot spots 31 on the IC device. The pedestals allow a much thinner TIM 20 of thickness “d” between the pedestal and the IC hot spot 31, versus the much thicker TIM 20 of thickness “D” in other areas of the fluid spreader. This allows improved heat transfer local to the pedestal area and preferentially from the hot spot 31 to the pedestal. Proper sizing of the pedestals (area and height) in comparison to the hot spots on the IC device can allow the heat transfer to be tailored and therefore the IC temperature to be tailored at specific locations on the IC device. In a further embodiment of the invention fluid spreaders or components with channels formed in them to affect fluid flow and thickness can be arranged opposed to one another, thereby further reducing the thickness between those two opposed surfaces.

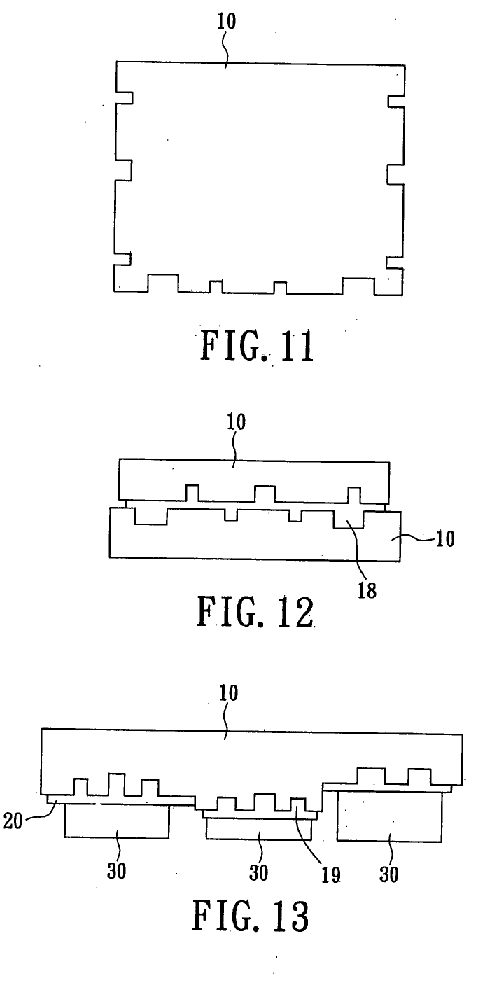

FIG. 10 is a cross sectional view of a fluid spreader 10 with channels 18 on opposite surfaces according to another embodiment of the invention. The scale, orientation and features of the channels 18 on each surface can be dissimilar. Channels 18 in this embodiment may also be arranged in radial patterns extending outward from the interior of the fluid spreader. Alternatively, channels 18 can be fully terminated within the periphery of the fluid spreader; specifically the channels 18 do not extend out to the periphery. FIG. 11 is a top view of a fluid spreader 10 with two or more non-parallel surfaces, with two or more of those surfaces having channels as described elsewhere in this invention. For example, the fluid spreader could be a cube with channels on each face. The scale, orientation and features of the channels on each surface can be dissimilar. Channels in this embodiment may also be arranged in radial patterns extending outward from the interior of the fluid spreader. FIG. 12 is a cross sectional view of two fluid spreaders, heat transfer structures or components (in any combination thereof) 10, each with its own channel 18 surface, the fluid spreaders, heat transfer structures or components arranged such that the surfaces with channels 18 are opposing each other in order to minimize the thickness of the fluid 20 dispersed between the surfaces according to another embodiment of the invention. In this case, since both opposing surfaces have channels 18 to aid in fluid flow the overall thickness of the fluid 20 between the surfaces will be less than if only one surface had channels 18. Channels 18 in this embodiment may also be arranged in radial patterns extending outward from the interior of the fluid spreader. Alternatively, channels 18 can be fully terminated within the periphery of the fluid spreader; specifically the channels 18 do not extend out to the periphery. In another embodiment of the invention the first surface could have areas of several different levels or planes—in order affect the fluid thickness and flow between two or more corresponding components. For example, the fluid spreader could have sections at three distinct levels to contact three separate ICs on a multi-chip module or System-in-Package.

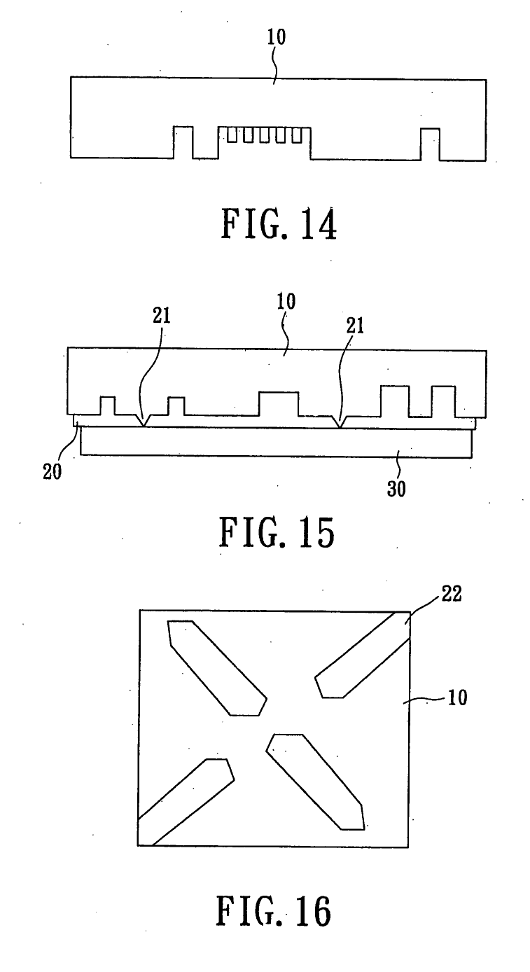

FIG. 13 is a cross sectional view of a fluid spreader 10 with a first surface of two or more levels, each level with channels 19, applied to two or more discrete devices 30 (such as semiconductor ICs or IC packages) according to another embodiment of the invention. This construct could be used, for example, on a multi-chip module or System-in-Package for housing ICs or other devices of varying heights. The multi-level fluid spreader 10 has varying levels corresponding to the varying levels of the ICs or devices 30. Channels 19 in this embodiment may also be arranged in radial patterns extending outward from the interior of the fluid spreader. Alternatively, channels 19 can be fully terminated within the periphery of the fluid spreader; specifically the channels 19 do not extend out to the periphery. In the case that the channels 19 are fully terminated within the periphery of the fluid spreader, since the channels 19 have no direct outlet for the fluid or TIM flow, the amount of fluid or TIM material must be controlled such that the material flows easily within the channels 19 and between the surface of the fluid spreader and the component. FIG. 14 is a cross sectional view of a fluid spreader 10 with certain channel areas that have flow restrictors (such as ridges, pin fin arrays, small walls, porous material or other similar devices that impede fluid flow) according to another embodiment of the invention. Channels in this embodiment may also be arranged in radial patterns extending outward from the interior of the fluid spreader. Alternatively, channels can be fully terminated within the periphery of the fluid spreader; specifically the channels do not extend out to the periphery. In another embodiment of the invention the surface has not only channels, but also reservoirs (sections of the surface with higher geometric volume than the channels) that can be used to store excess fluid flow or can be used a source of fluid to flow into the channels.

FIG. 15 is a cross sectional view of a fluid spreader 10 with protrusions or stand-offs 21 that provide a specific height or thickness differential between the fluid spreader and the component or device 30 according to another embodiment of the invention. In this case the standoffs 21 contact the surface of the component or device 30—preventing the fluid spreader 10 from coming any closer to the component or device surface, and allowing very exact and repeatable fluid thickness 20 between the two surfaces. FIG. 16 is a top view of a fluid spreader 10 with segmented channels (i.e. not continuous channels) according to another embodiment of the invention. These channel segments 22 may be arranged in any orientation and each have its own unique features (surface texture, depth, width variation or other features as defined above). Furthermore the fluid spreader 10 could have a combination of segmented channels 22 and full length channels. These segmented channels 22 in this embodiment may also be arranged in radial patterns extending outward from the interior of the fluid spreader 10. Alternatively, the segmented channels 22 can be fully terminated within the periphery of the fluid spreader 10; specifically the channels do not extend out to the periphery. According to one embodiment of the invention, a process to make a fluid spreader with channels as described is performed by metal injection molding and sintering of a suitable material such as copper, bronze, copper-molybdenum, copper-tungsten or steel.

The process includes steps of flattening the part of the fluid spreader surface that includes the channels after sintering by coining or stamping or by flattening by eliminating material from the surface by machining, grinding, polishing or other material removal methods. The process optionally includes a step of altering the geometry of the channels of the fluid spreader by etching, plating, or coating.

According to another embodiment of the invention, a process to make a fluid spreader with channels as described is provided. The process is performed by at least one of powder metallurgy, pressing and sintering of a suitable material such as copper. The process includes steps of flattening the part including the fluid spreader surface that has the channels after sintering; or altering the surface width or profile of the channels. The step of flattening the part including the channel surface can be achieved by coining, stamping, polishing, grinding or lightly machining. The step of altering the surface width or profile of the channel is achieved etching, plating or coating.

According to still another embodiment of the invention, a process to make a fluid spreader with channels as described is provided. The process performs machining, stamping, forging, etching or casting on two or more non-parallel surfaces or a continuously curvilinear surface of the channels. The continuously curvilinear surface can be a face of a cube for example.

In all above embodiments, an area can be further provided in the middle of the fluid spreader, or in one or other locations that are advantageous, for access by a vacuum pick-up head used in the assembly process. The spreader is picked up and placed onto the IC package and chip by a semi-automatic or fully automatic pick and place machine. This pick-up area meets the need of a flat area for the vacuum pick-up nozzle of the automatic pick and place machine. This pick-up area would be needed for any heat spreader with grooves/channels on the outside surface for TIM application.

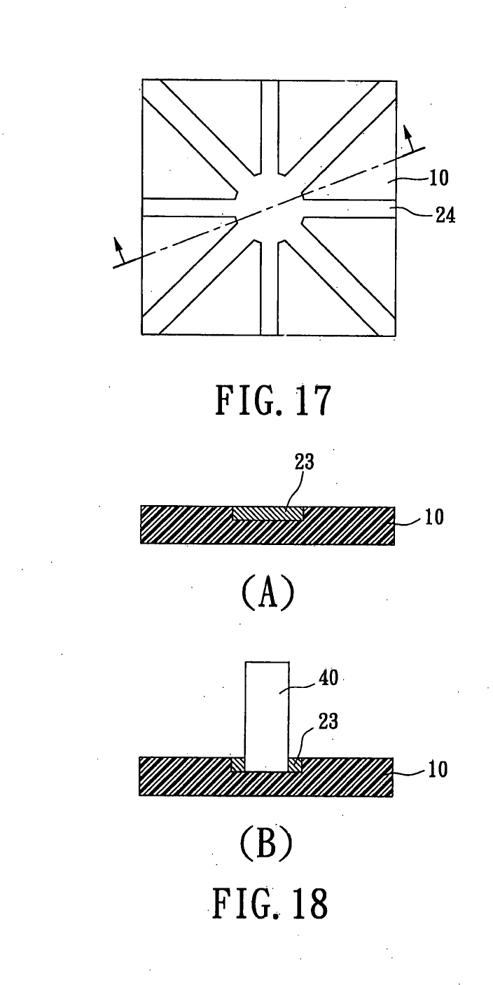

FIG. 17 shows a top view of an outside surface of a fluid spreader according to one embodiment of the invention. FIG. 18(A) is a cross-sectional view of a fluid spreader taken along the line A-A_in FIG. 17. FIG. 18(B) is a cross-sectional view, showing a vacuum pick-up head placed on a central area of the fluid spreader according to one embodiment of the invention. In FIG. 17, FIG. 18(A) and FIG. 18(B), the fluid spreader 10 has a central area on one surface on which a vacuum pick-up head 40 can be placed in an assembly process. The central area can be integrally formed with at least one channel 24 of the fluid spreader 10, and thus has the same features as recited above.

In all embodiments of the invention, the channels on each face or surface can be of different scale, orientation or other features.

An assembly of two or more fluid spreader as described opposing faces or surfaces with channels is further provided. In some embodiments, the protrusions or pedestals of the fluid spreaders partially or completely correspond to one another to form appropriate-sized reservoirs between two of the fluid spreaders of the assembly. In other embodiments, the channels of the fluid spreaders partially or completely correspond to one another to form appropriate-sized reservoirs between two of the fluid spreaders of the assembly. The reservoirs can receive appropriate volume of the fluid filled there between. This assembly thereby makes the fluids go to the very minimum thickness possible and some benefits can be derived by way of reduced fluid thickness

In view of foregoing, the present invention offers advantages over the prior art as follows. With a given amount of fluid (such as a TIM fluid), the thickness of the fluid between the first surface of the fluid spreader and the adjoining component or device (e.g. chip in a semiconductor IC package) is reduced and thereby the heat transfer efficiency (or other property that benefits from a thinner fluid layer) is improved. This design of fluid spreader is not just for thermal dissipation purpose in electronic field, but also can be applied to other fields that need to guide the fluid to flow through the channels to achieve the thinnest fluid layer possible.

With the use of the fluid spreader according to the invention, the flow of fluid or TIM between the spreader and a secondary component or components improves such that the force applied to the fluid spreader to promote that fluid flow is substantially reduced in comparison to a fluid spreader or heat transfer structure without channels or protrusions. It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A fluid spreader, comprising at least one surface, wherein the surface has at least one channel that continuously or discontinuously extends to an outer periphery of the surface.

2. The fluid spreader of claim 1, wherein the channel has varying widths along the channel.

3. The fluid spreader of claim 1, wherein more than one channel is formed on the first surface.

4. The fluid spreader of claim 1, wherein at least two channels are formed substantially non-parallel to one another.

5. The fluid spreader of claim 1, wherein the sides of each channel are configured in symmetrical or asymmetrical manner.

6. The fluid spreader of claim 1, wherein more than two channels of varying widths are arranged at equal or different intervals, in parallel or non-parallel manner.

7. The fluid spreader of claim 1, wherein the channel further has surface textures on the internal sidewalls or bottom thereof.

8. The fluid spreader of claim 1, wherein the channel further has serrated edges on its surface.

9. The fluid spreader of claim 1, wherein the channel has varying depths along the channel.

10. The fluid spreader of claim 9, wherein the depth of the channel varies from one internal sidewall to another opposite internal sidewall.

11. The fluid spreader of claim 1, wherein the change in depth in one channel is regular or irregular, symmetrical or asymmetrical.

12. The fluid spreader of claim 1, wherein the channel has a convex, semi-circle, V-shaped or other non-rectangular profile.

13. The fluid spreader of claim 1, wherein the channel on one surface is of different scale, orientation or other features versus the channels on other surfaces.

14. The fluid spreader of claim 1, wherein the fluid spreader has two or more surfaces, and at least one surface is continuously curvilinear and at least the other one is of a cube.

15. The fluid spreader of claim 1, wherein the surface has two or more levels to match up with different devices at different levels.

16. The fluid spreader of claim 15, wherein each level of the channel is of different scales, orientation or surface textures.

17. The fluid spreader of claim 1, wherein one or more channels have surface textures along a portion of a channel, portions of channels or the whole channels.

18. The fluid spreader of claim 1, wherein certain channel areas have flow restrictors that impede fluid flow.

19. The fluid spreader of claim 18, wherein the flow restrictors include ridges, pin fin arrays, small walls, porous material or other similar devices.

20. The fluid spreader of claim 1, further comprising small protrusions or standoffs that come into contact with semiconductor components or other devices to which the fluid spreader is joined.

21. The fluid spreader of claim 1, wherein the channel has one or more segments along the whole length thereof.

22. The fluid spreader of claim 1, further comprising one or more reservoirs to store or collect fluid in certain areas thereof.

23. The fluid spreader of claim 1, wherein the channels are arranged in radial patterns extending outward from an interior of the fluid spreader.

24. The fluid spreader of claim 1, wherein the channels are fully terminated within the periphery of the fluid spreader.

25. The fluid spreader of claim 1, wherein the fluid spreader further has a vacuum pick-up area integrally formed with at least one channel.

26. The fluid spreader of claim 1, wherein the depth of the channel varies from one section of the channel to another section of the channel, in a lengthwise direction along the channel.

27. A fluid spreader comprising at least one pedestal or protrusion on at least one of its surfaces, wherein the at least one pedestal or protrusion lines up with at least one hot spot on a chip or other electronic device.

28. The fluid spreader of claim 27, wherein the spreader is in the range of 8 microns to 50 microns tall.

29. The fluid spreader of claim 27, wherein each of the pedestals has an area from tens of square microns to tens of square millimeters.

30. A semiconductor package, comprising at least a fluid spreader, at least one semiconductor component, and a TIM layer between the fluid spreader and the semiconductor component, wherein the fluid spreader further has at least one surface with at least one channel which continuously or discontinuously extends to an outer periphery of the surface.

31. The semiconductor package of claim 30, wherein the TIM layer includes thermal greases, phase change materials, thermal adhesives, thermally conductive compounds, solders, liquid metals, braze alloys, thermal conductive elastomers, thermally conductive adhesive tapes, and thermally conductive pads.

32. The semiconductor package of claim 30, wherein the channels are fully terminated within the periphery of the fluid spreader.

33. The semiconductor package of claim 30, wherein the fluid spreader further has a vacuum pick-up area integrally formed with at least one channel.

34. The semiconductor package of claim 30, wherein the depth of the channel varies from one section of the channel to another section of the channel, in a lengthwise direction along the channel.

35. The semiconductor package of claim 30, wherein the channel has varying depths along the whole channel.

36. The semiconductor package of claim 30, wherein the channels are arranged in radial patterns extending outward from an interior of the fluid spreader.

37. The semiconductor package of claim 30, wherein the channel on one surface is of different scale, orientation or other features versus the channels on other surfaces.

38. The semiconductor package of claim 30, wherein the fluid spreader has two or more surfaces, and at least one surface is continuously curvilinear and at least the other one is of a cube.

39. The semiconductor package of claim 30, wherein the fluid spreader is a heat transfer structure.

40. The semiconductor package of claim 30, wherein more than two channels of varying widths are arranged at equal or different intervals, in parallel or non-parallel manner.

41. The semiconductor package of claim 30, wherein the channel further has surface textures on internal sidewalls or bottom thereof.

42. The semiconductor package of claim 41, wherein the surface textures include serrated edges.

43. The semiconductor package of claim 30, wherein there is at least one pedestal or protrusion on at least one of its surfaces.

44. The semiconductor package of claim 43, wherein the pedestal or protrusion is located to correspond to hot spots, cold spots or other specific areas on the component.

45. The semiconductor package of claim 30, wherein the semiconductor component is an IC chip.

46. The semiconductor package of claim 30, wherein the channel has varying depths along the whole channel.

47. The semiconductor package of claim 30, wherein the channel on one surface is of different scale, orientation or other features versus the channels on other surfaces.

48. The semiconductor package of claim 30, wherein the surface has two or more levels to match up with different semiconductor components at different levels.

49. The semiconductor package of claim 30, further comprising small protrusions or standoffs that come into contact with the semiconductor components or other devices to which the fluid spreader is joined.

50. The semiconductor package of claim 30, wherein more than one channel is formed on the first surface.

51. The semiconductor package of claim 30, wherein at least two channels are formed substantially non-parallel to one another.

52. The semiconductor package of claim 30, wherein the depth of the channel varies from one internal sidewall to another opposite internal sidewall.

53. The semiconductor package of claim 30, wherein the change in depth in one channel is regular or irregular, symmetrical or asymmetrical.

54. The semiconductor package of claim 30, wherein the channel has a convex, semi-circle, V-shaped or other non-rectangular profile.

55. The semiconductor package of claim 30, wherein the surface has two or more levels to match up with different devices at different levels.

56. The semiconductor package of claim 55, wherein each level of the channel is of different scales, orientation or surface textures.

57. The semiconductor package of claim 30, wherein one or more channels have surface textures along a portion of a channel, portions of channels or the whole channels.

58. The semiconductor package of claim 30, wherein certain channel areas have flow restrictors that impede fluid flow.

59. The semiconductor package of claim 30, wherein the flow restrictors include ridges, pin fin arrays, small walls, porous material or other similar devices.

60. The semiconductor package of claim 30, further comprising small protrusions or standoffs that come into contact with semiconductor components or other devices to which the fluid spreader is joined.

61. The semiconductor package of claim 30, wherein the channel has one or more segments along the whole length thereof.

62. The semiconductor package of claim 30, further comprising one or more reservoirs to store or collect fluid in certain areas thereof.

63. A process to make a fluid spreader as described in claim 1, comprising:
flattening the part including the fluid spreader surface containing the channels after sintering.

64. The process of claim 63, wherein the process includes altering the surface width or profile of the channels.

65. The process of claim 63, wherein the channels are fully terminated within the periphery of the fluid spreader.

66. The process of claim 63, wherein the step of flattening the part including the channel surface is achieved by coining, stamping, polishing, grinding or lightly machining.

67. The process of claim 63, further comprising a step of altering the surface width or profile of the channel by etching, plating or coating.

68. The process of claim 63, wherein the channels are arranged in radial patterns extending outward from an interior of the fluid spreader.

69. The process of claim 63, wherein the fluid spreader further has a vacuum pick-up area integrally formed with at least one channel.

70. The process of claim 63, wherein the depth of the channel varies from one section of the channel to another section of the channel, in a lengthwise direction along the channels.

71. The process of claim 63, further comprising at least one steps of powder metallurgy, pressing and sintering of a fluid spreader material.

72. The process of claim 63, wherein the spreader material is copper, bronze, copper-molybdenum, copper-tungsten, aluminum or steel.

73. The process of claim 63, wherein the depth of the channel varies from one section of the channel to another section of the channel, in a lengthwise direction along the channel.

74. The process of claim 63, wherein the channels are fully terminated within the periphery of the fluid spreader.

75. A process to make a fluid spreader as described in claim 1, comprising:
flattening the part of the fluid spreader including the fluid spreader surface containing the channels after sintering by coining or stamping or flattening by removing material by machining, grinding, polishing or similar method;

76. The process of claim 75, further comprising the altering of the surface geometry, width or profile of the channel of the fluid spreader.

77. The process of claim 75, further comprising injection molding and sintering of a spreader material.

78. The process of claim 75, wherein the spreader material is copper, bronze, copper-molybdenum, copper-tungsten, aluminum or steel.

79. The process of claim 75, wherein the step of altering the surface geometry of the channel of the fluid spreader is achieved by sintering first, and then etching, plating or coating.

80. An assembly of fluid spreaders, comprising two or more fluid spreaders as defined in claim 1, wherein surfaces of the fluid spreaders with the channels thereon face-to-face each other.

81. The assembly of fluid spreaders of claim 80, wherein the fluid spreaders have protrusions or pedestals partially or completely corresponding to one another to form appropriate-sized reservoirs between two of the fluid spreaders of the assembly.

82. The assembly of fluid spreaders of claim 80, further comprising fluids between the fluid spreaders.

83. The assembly of fluid spreaders of claim 80, wherein the fluids include thermal greases, phase change materials, thermal adhesives, thermally conductive compounds, solders, liquid metals, braze alloys, thermal conductive elastomers, thermally conductive adhesive tapes, and thermally conductive pads.

84. The assembly of claim 80, wherein the depth of the channel varies from one section of the channel to another section of the channel, in a lengthwise direction along the channel.

85. The assembly of claim 80, wherein the channels are arranged in radial patterns extending outward from an interior of the fluid spreader.

86. The assembly of claim 80, wherein channels are fully terminated within the periphery of the fluid spreader.

87. The assembly of claim 80, wherein the fluid spreader further has a vacuum pick-up area integrally formed with at least one channel.

88. The assembly of claim 80, wherein the channels has at least one pedestal or protrusion on its surface.

89. A semiconductor package, comprising at least a fluid spreader, at least one semiconductor component, and a TIM layer between the fluid spreader and the semiconductor component, wherein the fluid spreader further includes at least one pedestal or protrusion on at least one of its surfaces, wherein the at least one pedestal or protrusion lines up with at least one hot spot on a chip or other electronic device to which the fluid spreader is joined.

90. The semiconductor package r of claim 89, wherein the spreader is in the range of 8 microns to 50 microns tall.

91. The semiconductor package of claim 89, wherein each of the pedestals has an area from tens of square microns to tens of square millimeters.

92. The semiconductor package of claim 89, wherein the TIM layer includes thermal greases, phase change materials, thermal adhesives, thermally conductive compounds, solders, liquid metals, braze alloys, thermal conductive elastomers, thermally conductive adhesive tapes, and thermally conductive pads.

93. The semiconductor package of claim 89, wherein the fluid spreader further has a vacuum pick-up area integrally formed with at least one channel.

94. The semiconductor package of claim 89, further having at least one channel with depth varying from one section of the channel to another section of the channel, in a lengthwise direction along the channel.

95. The semiconductor package of claim 94, wherein the channel has varying depths along the whole channel.

96. The semiconductor package of claim 94, wherein the channels are arranged in radial patterns extending outward from an interior of the fluid spreader.

97. The semiconductor package of claim 94, wherein the channel on one surface is of different scale, orientation or other features versus the channels on other surfaces.

98. The semiconductor package of claim 89, wherein the fluid spreader has two or more surfaces, and at least one surface is continuously curvilinear and at least the other one is of a cube.

99. The semiconductor package of claim 89, wherein the fluid spreader is a heat transfer structure.

100. The semiconductor package of claim 94, wherein more than two channels of varying widths are arranged at equal or different intervals, in parallel or non-parallel manner.

101. The semiconductor package of claim 94, wherein the channel further has surface textures on internal sidewalls or bottom thereof.

102. The semiconductor package of claim 101, wherein the surface textures include serrated edges.

103. The semiconductor package of claim 101, wherein the channel has varying depths along the whole channel.

104. The semiconductor package of claim 94, wherein the surface has two or more levels to match up with different semiconductor components at different levels.

105. The semiconductor package of claim 94, wherein more than one channel is formed on the first surface.

106. The semiconductor package of claim 94, wherein at least two channels are formed substantially non-parallel to one another.

107. The semiconductor package of claim 94, wherein the depth of the channel varies from one internal sidewall to another opposite internal sidewall.

108. The semiconductor package of claim 107, wherein the change in depth in one channel is regular or irregular, symmetrical or asymmetrical.

109. The semiconductor package of claim 94, wherein the channel has a convex, semi-circle, V-shaped or other non-rectangular profile.

110. The semiconductor package of claim 89, further having a surface with two or more levels to match up with different devices at different levels.

111. The semiconductor package of claim 94, wherein each level of the channel is of different scales, orientation or surface textures.

112. The semiconductor package of claim 94, wherein one or more channels have surface textures along a portion of a channel, portions of channels or the whole channels.

113. The semiconductor package of claim 94, wherein certain channel areas have flow restrictors that impede fluid flow.

114. The semiconductor package of claim 113, wherein the flow restrictors include ridges, pin fin arrays, small walls, porous material or other similar devices.

115. The semiconductor package of claim 94, wherein the channel has one or more segments along the whole length thereof.

116. The semiconductor package of claim 89, further comprising one or more reservoirs to store or collect fluid in certain areas thereof.
